(19) United States
(12) Patent Application Publication
(10) Pub. No.: US 2025/0261334 A1
(43) Pub. Date: Aug. 14, 2025

(54) MODULAR SUPPORT ASSEMBLY FOR DATA CENTER COOLING

(71) Applicant: QTS Realty Trust, LLC, Overland Park, KS (US)

(72) Inventors: Christopher Lane Anderson, Irving, TX (US); Alec McGinnis, Fayetteville, GA (US)

(21) Appl. No.: 19/052,916

(22) Filed: Feb. 13, 2025

Related U.S. Application Data
(60) Provisional application No. 63/553,090, filed on Feb. 13, 2024.

(51) Int. Cl. H05K 7/20

(52) U.S. Cl. CPC H05K 7/20272; H05K 7/2079

(57) ABSTRACT

A modular structure for cooling a set of servers includes a plurality of modular frame assemblies, each frame assembly including a plurality of frames affixed to one another with a plurality of longitudinal struts, assembled off-site from a data center containing the set of servers, wherein each frame assembly is independently affixed to a data center structure proximate the set of servers, and a plurality of modular fluid distribution assemblies, with each respective fluid distribution assembly affixed to a respective one of the frame assemblies, and with adjacent ones of the modular fluid distribution assemblies fluidly coupled to one another, wherein the fluid distribution assemblies are fluidly coupled with a cooling fluid source in the data center.

### CROSS-REFERENCE TO RELATED APPLICATION

This application claims the benefit of priority to U.S. provisional application No. 63/553,090, filed on Feb. 13, 2024, which is hereby incorporated by reference in its entirety.

### BACKGROUND

Data centers require expansive cooling systems in order to operate, as the simultaneous operation of so many processors in a confined space leads to high temperatures, which-if not remediated-can degrade computing performance or otherwise interrupt data center activity.

### BRIEF DESCRIPTION OF THE DRAWINGS

FIG. 1 is a perspective view of a frame assembly and partial cooling fluid distribution assembly for a data center cooling system.

FIG. 2 is a process flow mounting frame assemblies according to FIG. 1 in a data center.

FIG. 3 is a perspective view of the frame assemblies of FIG. 2 deployed with a set of servers.

FIG. 4 is a schematic front view of the assemblies and set of servers of FIG. 3.

FIG. 5 is a perspective view of a cooling assembly portion.

FIG. 6 is a flow chart illustrating an example method of assembling a cooling assembly for one or more servers.

### DETAILED DESCRIPTION

Various embodiments of this disclosure include a modular system for providing cooling to computing equipment, including but not limited to servers in a data center. Because servers generate an immense amount of radiative heat during operation, it is crucial to provide sufficient cooling to regulate the servers' temperature. While many different methods of cooling have been utilized—including forced air or the use of cool water-filled piping—each cooling system faces a similar issue: on-site construction of cooling systems must compete for time, space, and resources with the construction of the rest of the data center. In particular, certain skilled labor, such as welding, may be in high demand in the construction process at the time that cooling assembly supports are typically installed. Further, installation of cooling infrastructure relies on the building itself having been completed, and thus an extended time period of building and installation of cooling infrastructure can delay the installation and ultimate operation of the servers for which the data center is being built. Accordingly, it is advantageous for a cooling system to be able to be built and assembled off-site, transported to the data center as constructed modular assemblies, and then installed and connected to in-building infrastructure (rather than completely constructed) on-site in the data center in order to advance the operations of the data center and improve its time to being online. The system as described herein accomplishes this by providing a modular frame unit that may be used to build a cooling assembly of a desired size by coupling a chosen quantity of identical modular frame units. The assembled frame units are then attached to a ceiling of the data center. In addition, the modular frame unit may include structural support for both cooling assemblies (e.g., piping) and for electrical assemblies (e.g., wiring harnesses) so that installation and connection of both cooling and electrical hardware is simplified on-site.

In some embodiments, the modular frame assemblies may be assembled offsite in conjunction with cooling fluid distribution assemblies. That is, inflow and outflow piping, taps to connect those inflows and outflows to server cooling devices, and other distribution components may be assembled and affixed to the frame assemblies offsite. Those fluid distribution assemblies may then be connected to each other (e.g., for continuity of inflow and outflow through a server row) and to a fluid source on site in the data center. Like assembling the frame assemblies offsite, assembling the cooling fluid distribution assemblies offsite permits the separation of labor needs between the assemblies (which can be built at a convenient time before their installation) and the construction of the data center itself.

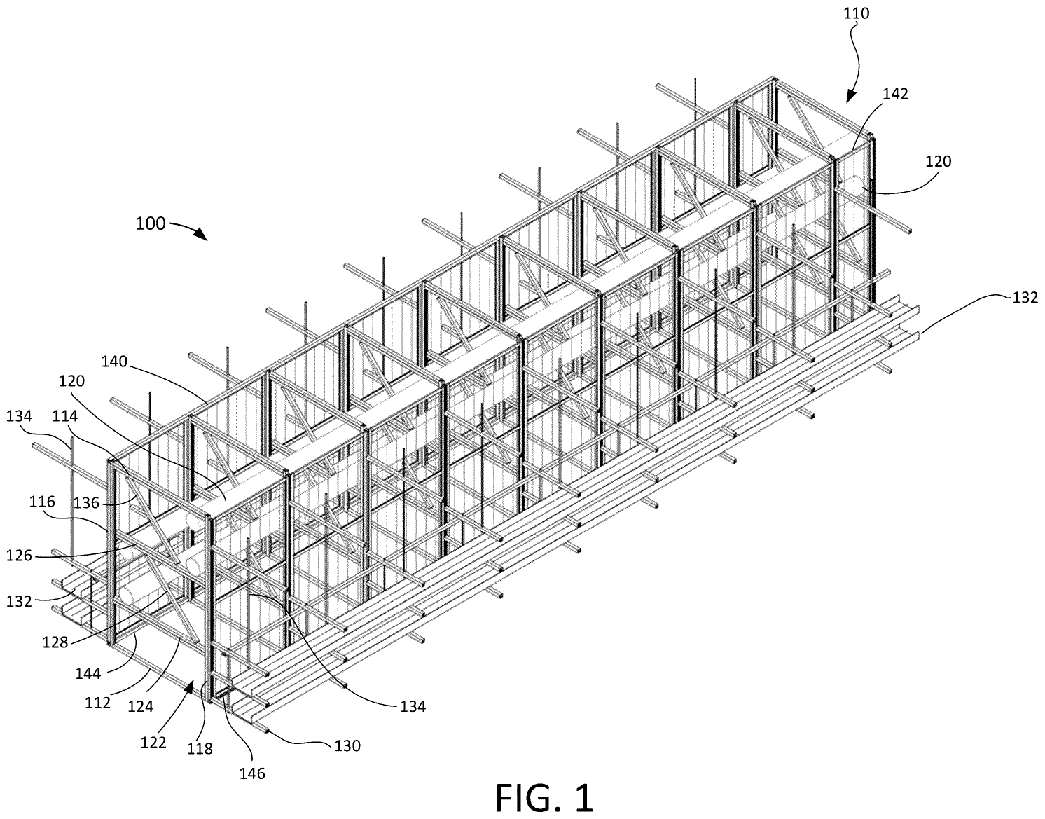

FIG. 1 is a perspective view of a frame unit 100. As shown, the frame unit 100 may include a central support body 110, at least one water pipe 120, and a plurality of side support extensions 130. The central support body 110 may be substantially rectangular (e.g., in a cross-section taken across any of the Z-axis, Y-axis, or X-axis), and may be formed of interconnected struts, which may offer high strength at relatively low weight. Specifically, the support body 110 may be formed of a rectangular frame of a lower horizontal strut 112 and an upper horizontal strut 114 coupled to each other by two vertical struts 116, 118. The struts 112, 114, 116, 118 may surround and may define a central gap 122 through which a desired number of water pipes 120 may extend and which may be sized to support a needed quantity of pipes 120. The support body 110 may further include one or more (e.g., two) additional horizontal struts 124, 126 extending between the vertical struts 116, 118, and diagonal struts 128, 136 that each extends between a respective set of horizontal struts 124, 126, 114.

A set of connected struts 112, 114, 116, 118, 124, 126, 128, 136 may define a single frame, and a plurality of frames may be coupled together via longitudinal struts. For example, longitudinal struts 140, 142, 144, 146 may extend from each corner of the rectangular frames. Accordingly, the frame unit 100 may comprise a plurality of rectangular frames coupled together by a plurality of longitudinal struts.

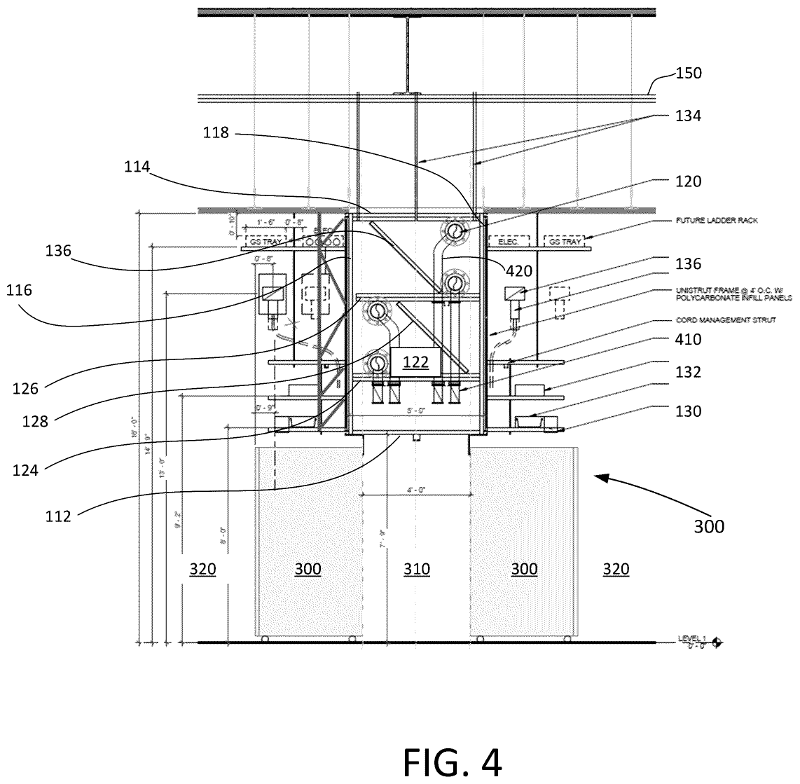

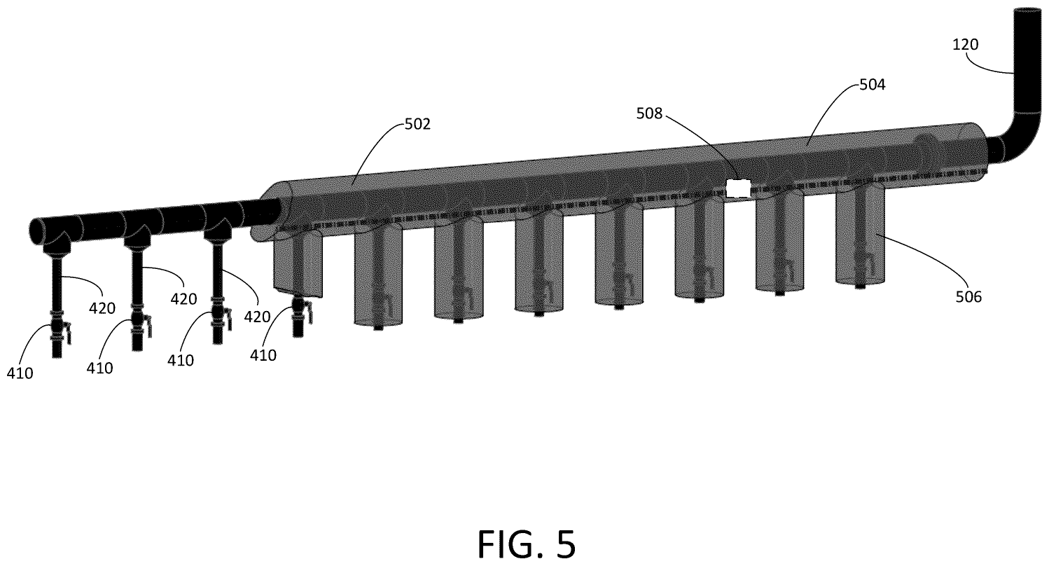

The at least one pipe 120 may be structured to carry a liquid (e.g., water), and may be positioned within and extend longitudinally (e.g., along a Y-axis that is parallel with the ground when the frame unit 100 is installed in a building) through the central gap 122. Although the frame unit 100 of FIG. 1 is shown to include four pipes 120, this disclosure should not be read as limited to only four pipes 120 and should be read as inclusive of any number of desired pipes 120. During installation of a modular frame assembly 100 at a data center, each pipe 120 may be connected to one or more cooling units on one or more servers or server racks. Accordingly, as will be shown in FIGS. 4 and 5, each pipe 120 may include one or more vertical taps, each used for exchange of liquid with the pipe, and each of which may terminate in a valve. In some embodiments, one pipe 120 may serve as a cooling intake and another pipe 120 as a cooling output, such that the liquid flowing through the cooling units serves as a heat sink and is recooled before being recirculated to the cooling units.

In some embodiments, each pipe 120 may rest on top of a horizontal strut 112, 114, 124, 126, or may rest under and be supported by a horizontal strut 112, 114, 124, 126. A pipe 120 may be secured to a horizontal strut 112, 114, 124, 126 via a band, clamp, or tie made of metal, nylon, or another appropriate material that is wrapped around the pipe 120 and secured to the strut 112, 114, 124, 126 via one or more fasteners.

A plurality of side extensions 130 may protrude from the central body 110 along the X-axis, which may be parallel to the ground once the frame unit is installed in a building. In some embodiments, each side extension 130 may be monolithically-formed with the central frame (e.g., such as by welding). As shown, four side extensions 130 protrude from each vertical beam of the central body 110. The lower two side extensions 130 on each side may hold a trough 132 shaped to hold cables, wires, or other accessories associated with the servers 300. A suspension wire 134 may be fixed to each third side extension 130 and fed through the fourth side extension 130 before being fixed to a ceiling (e.g., ceiling frame 150).

In some embodiments, struts 112, 114, 116, 118, 124, 126, 128, 136 may be affixed to one another by welding, metal fasteners (e.g., bolts with angle joints, etc.), or other appropriate affixation techniques. In some embodiments, the techniques used to assemble a frame 150 (e.g., used to affix struts 112, 114, 116, 118, 124, 126, 128, 136 to one another) may be different from the affixation techniques used to affix the frame assembly 100 to a building. For example, welding may be employed when assembling the frame unit 100, whereas only fasteners may be needed to affix the frame unit 100 to a building.

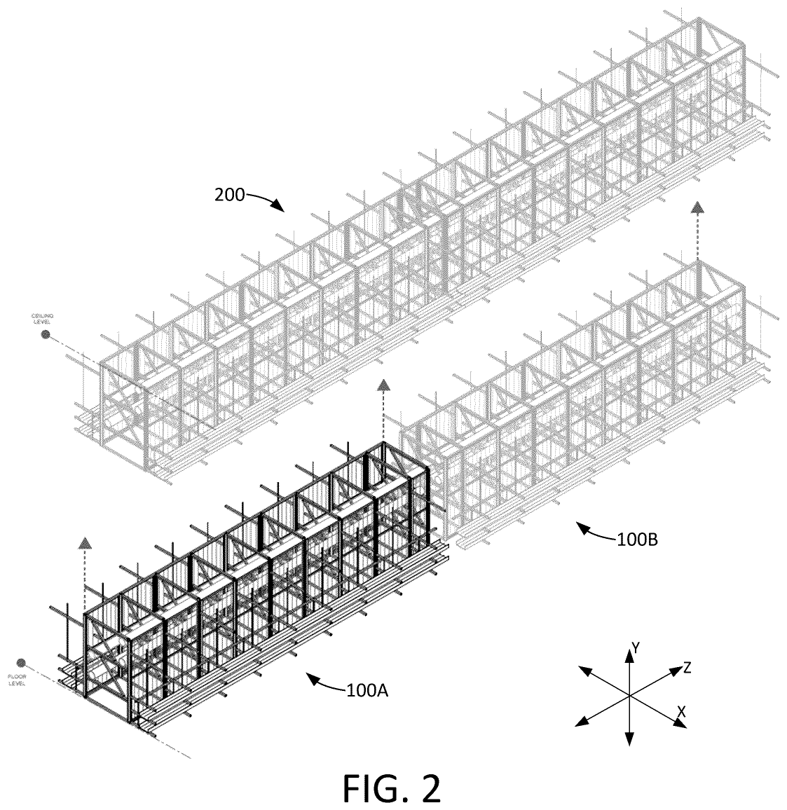

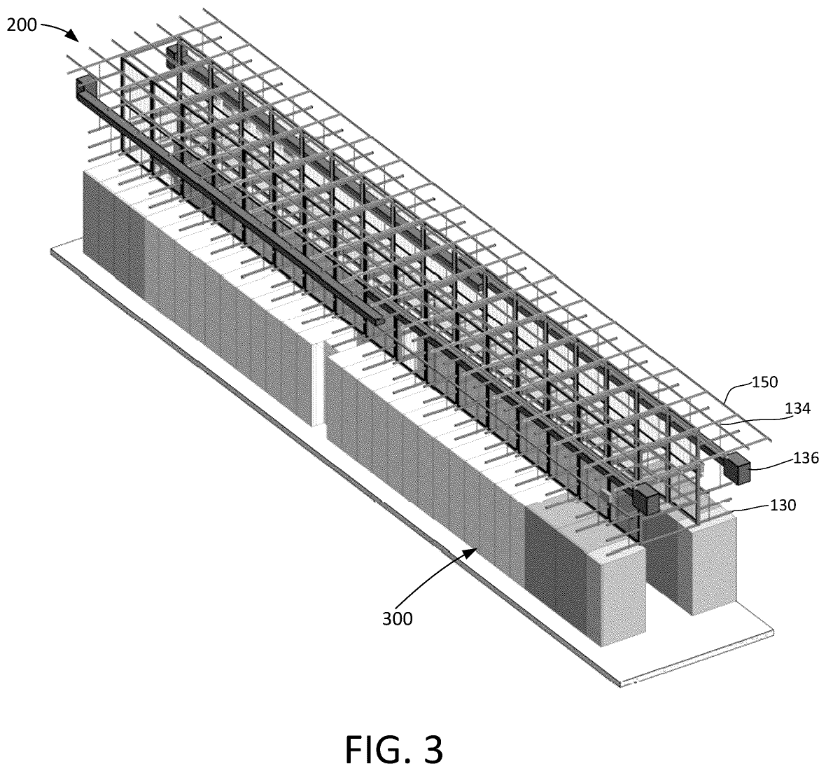

As shown in FIG. 2, a first frame unit 100A may be attached to a second frame unit 100B end-to-end along the Z-axis to form a frame assembly 200. In some embodiments, the trough 132 may be attached to the frame unit 100 prior to connecting the multiple frame units. In some embodiments, the trough 132 may be attached to the frame assembly 200 following assembly of multiple frame units 100 together. Like the trough 132, the pipes 120 may be installed within the frame unit 100 prior to full assembly, or within the frame assembly 200 once assembled. Once the frame units 100 are assembled at floor level, the frame assembly 200 may be elevated and attached to ceiling 150 via the suspension wires 134 and/or by fastening top struts 114, 140, 142 to the building structure. Alternatively, an individual frame unit 100 may be attached to ceiling 150 before being coupled to another frame unit 100, i.e., frame units 100 may be suspended before being attached to each other. Still further, in some embodiments, frame units 100 may be independently suspended from ceiling 150 and may not be mechanically coupled to other frame units 100 other than by virtue of continuity of pipes 120 and/or other non-structural components. FIG. 3 shows the elevated frame assembly 200 in position above the server racks 300 (which may be filled with servers after assembly of the frame assembly 200), with the troughs 132 and pipes 120 omitted for clarity. As shown, electrical equipment 136 may be further coupled to the central body 110.

FIG. 4 is a schematic end view of the frame unit 100 in elevated position above the server racks 300. The frame unit may further include a plurality of valves 410 (e.g., one or more valves 410 per pipe 120) for fluidly coupling the pipes 120 to cooling units (not shown) installed on the server racks 300 for cooling servers and other computing equipment. The valves 410 may be provided at the end of cooling fluid supply or return taps 420.

FIG. 5 is a perspective view of a cooling assembly portion 500 that may find use with the frame unit 100. The cooling assembly portion 500 includes a main pipe 120 and a plurality of cooling fluid supply or return taps 420, each terminating in a valve 410. The cooling assembly portion 500 may further includes a water-resistant sheath 502 that may cover all pipe headers (including main pipe 120) and supply/return taps 420. The sheath 502 may prevent significant leaks and indiscriminate spraying in the event of a leak or excess condensation, instead containing, and directing the disposition of any such moisture to a desired location, such as a floor portion with a drain or water collection recess.

The sheath 502 may be or may include a waterproof or water-resistant material that contains leaks and condensation from the pipe 120 and funnels any such leaks and condensation to a location where liquid can safely drip down from the pipe. In some embodiments, the sheath may be or may include a polymer material, such as neoprene rubber or other rubber, treated nylon, rubberized cotton or other rubberized material, a polyethylene wrap, a polyvinyl chloride (PVC) coating or wrap, a thermal shrink sleeve such as polyethylene shrink, a fiberglass wrap, and/or another appropriate material.

The sheath 502 may be circumferentially sealed around each pipe 120, in some embodiments. For example, a longitudinal portion of the sheath 502 may be wrapped around the pipe 120, and a slit in the sheath 502 that permitted it to be placed on the pipe 120 may be sealed with adhesive, tape, heat, or another sealant.

The sheath 502 may include portions 504 for a pipe 120 and portions 506 for taps 420 that are assembled to the piping separately. In some embodiments, seams between portions 504, 506 may be sealed with adhesive, heat, or another sealant. The seams between portions 504, 506 may be sealed at the same time as, or separately from, slits in the portions themselves.

One or more moisture sensor assemblies 508 may be provided in the sheath 502 for detection of leaks and/or excess condensation. A moisture sensor may be or may include, for example, a resistive moisture sensor, capacitive moisture sensor, infrared moisture sensor, and/or any other appropriate type of sensor. The assembly portion 500 (or, more broadly, the assembly 100 of FIG. 1) may include a plurality of moisture sensor assemblies spaced throughout the assembly 100 or assembly portion 500. For example, a moisture sensor assembly may be provided at three-foot intervals, five-foot intervals, ten-foot intervals, or another interval, along the pipe 120.

Each moisture sensor assembly 508 may include the sensor itself as well as a circuit board and one or more output devices. An output device may include, for example, one or more of a buzzer, speaker, or other audio output, an LED or other light, and/or a wireless transmitter that transmits a status of the moisture sensor to an external controller. For example, a moisture sensor assembly may transmit its status and identifier to a central controller for the broader infrastructure of a data center, and the central controller may determine the location of a leak or other excess moisture based on transmissions received from one or more sensors and known locations of those sensors based on their identifiers.

In some embodiments, where the moisture sensor includes an audio output or visual output, an aperture may be provided in the sheath 502 for passage of wiring for the audio and/or visual output through the sheath wall, or for the audio and/or visual output mechanism itself to protrude through the sheath wall. Any such aperture may be sealed around the passed wiring, audio output mechanism, and/or visual output mechanism. For example, the sealant may include a silicone sealant, caulk, epoxy, and/or another appropriate sealant given the material of the sheath 502.

Moisture sensor assemblies 508 may be used even in embodiments without a sheath 502. For example, one or more moisture sensor assemblies may be coupled directly to the pipe 120 and/or all pipes of an assembly 100.

Portions of the sheath 502 are cut away in FIG. 5 for visual clarity. It should be understood that any and/or all pipes 120 and/or taps 420 may be enveloped by the sheath 502, in embodiments.

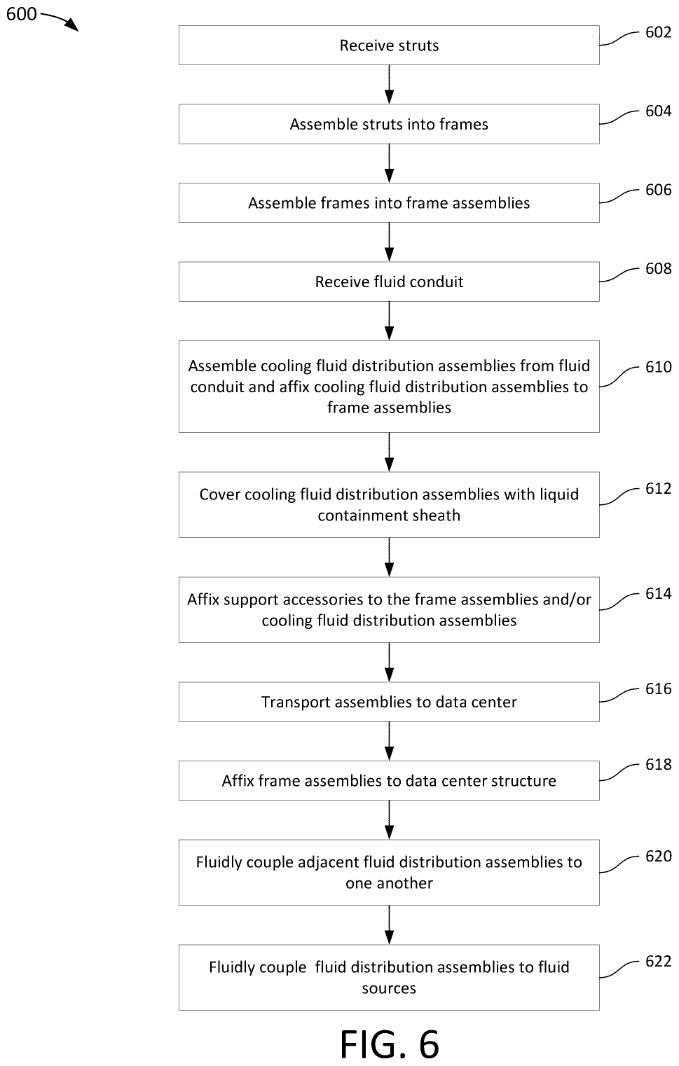

FIG. 6 is a flow chart illustrating an example method 600 of assembling and installing a colling assembly for a set of servers. The method 600 may improve the efficiency of data center construction. In embodiments, by separating the construction of the cooling assembly from the construction of the larger data center, construction of both the cooling assembly and the data center can be completed more efficiently. Accordingly, as will be described in detail below, certain assembly aspects may be performed at a first location, separate from the data center, and other assembly aspects may be performed at a second location (the data center itself).

The method 600 may include, at block 602, receiving a plurality of struts (e.g., struts 112, 114, 116, 118, 124, 126, 128, 136). The struts may all be identical to one another in size, or may be a variety of sizes (e.g., widths, thicknesses, and lengths). The structs may all be identical to one another in cross-sectional shape, or may be a variety of shapes (e.g., I-beam, box construction, etc.). The dimensions of the struts (e.g., material thickness) may be determined according to an anticipated load to be borne by cooling and other infrastructure supported by the struts.

The method 600 may further include, at block 604, assembling a plurality of struts into a plurality of frames. Each frame may include, for example, an upper horizontal strut, a lower horizontal strut, a left vertical strut, and a right vertical strut defining a rectangular frame outline. A frame may further include one or more additional horizontal struts extending from the left vertical strut to the right vertical strut and/or one or more additional vertical struts extending from the lower horizontal strut to the upper horizontal strut.

Assembling struts into a frame may include affixing each strut to one or more other struts. Struts may be affixed to one another by welding, in some embodiments.

The method 600 may further include, at block 606, assembling a plurality of frames into one or more (e.g., a plurality of) frame assemblies. Block 606 may include, for example, affixing adjacent frames to one another via a plurality of longitudinal struts. Frames may be affixed to longitudinal struts (that is, horizontal and/or vertical struts may be affixed to longitudinal struts) by welding, in some embodiments.

Block 608 may further include, in some embodiments, affixing one or more eye bolts or other structures that can be used to attach the completed frame assembly to a data center structure, as described below in block 618. For example, block 608 may include affixing a plurality of eye bolts to the upper struts of the frame assembly, for example. The eye bolts may be affixed by welding, in some embodiments.

In addition to or instead of eye bolts or separate structures, block 608 may include forming loops or other receiving structures in the struts themselves.

In some embodiments, blocks 604, 606 may be performed in conjunction, rather than sequentially, to assemble a frame assembly.

A frame assembly that is assembled at blocks 604, 606 may be of a size so as to fit on a standard flatbed truck (that is, a truck bed intended to accommodate a standard shipping container) or in a standard shipping container, in some embodiments. That is, a frame assembly may fit within dimensions of 20 feet in length, 8 feet in width, and 8.5 feet in height. Alternatively, a frame assembly may fit within dimensions of 40 feet in length, 8 feet in width, and 8.5 feet in height. Alternatively, a frame assembly may fit within a height dimension of 9.5 feet, with a length and width as noted above.

The method 600 may further include, at block 608, receiving a plurality of fluid conduits (e.g., pipes 120, taps 420, valves 410, and the like). The quantity and dimensions of fluid conduit may be determined according to an anticipated cooling need of the set of servers or other computing devices to be cooled using infrastructure supported by the frame assembly.

The method 600 may further include, at block 610, assembling a cooling fluid distribution assembly comprised of the received fluid conduit. The cooling fluid distribution assembly may include, for example, inflow pipes, outflow pipes, and taps. The quantity of taps may be determined according to an arrangement of a cooling device or arrangement for the intended set of servers or other computing devices. Block 610 may include affixing the cooling fluid distribution assembly to the frame assembly. For example, pipes may be affixed to struts with bands, clamps, ties, etc. Block 610 may further include coupling one or more moisture sensors to the cooling fluid distribution assembly, such as coupling sensor assemblies at predetermined intervals along the inflow and/or outflow pipes. Where such moisture sensor assemblies are provided, block 610 may further include routing power wiring for the sensor assemblies along the cooling fluid distribution assembly, terminating in ported electrical connectors for connection to a power supply and/or to other cooling fluid distribution assembly moisture sensors, for example.

The method 600 may further include, at block 612, covering one or more portions of the cooling fluid distribution assembly with a liquid containment sheath. As described above with respect to FIG. 5, the sheath may include a waterproof or water-resistant material that contains leaks and excess condensation from the cooling fluid distribution assembly and directs any such moisture to a safe location for its exit.

Block 612 may include inserting cooling pipes, taps, and/or other aspects of the cooling fluid distribution assembly through respective sheath portions. Block 612 may further include sealing junctions of sheath portions in a watertight manner, such as with adhesive, heat, tape (e.g., where the sheath comprises heat shrink or another heat-deformable material), and/or another sealant. Block 612 may further include sealing longitudinal slits that were utilized to place sheath portions in a similar manner.

In some embodiments, block 612 may include forming one or more apertures in the sheath for the passage of moisture sensor assemblies, or portions of such assemblies, such as wiring, audio or visual outputs, and the like. When such apertures are formed, block 612 may further include sealing those apertures about the devices that are passed through the apertures, such as with epoxy, adhesive, etc.

The method 600 may further include, at block 614, affixing one or more support accessories to the frame assembly and/or cooling fluid distribution assembly. The support accessories may include, for example, one or more longitudinal trays, troughs, and/or other multi-use support infrastructure.

Blocks 602, 604, 606, 608, 610, 612, 614 may be performed at a first location, in some embodiments, such as a location different from a data center in which the frame assembly and cooling fluid distribution assembly are to be deployed.

The method 600 may further include, at block 616, transporting the assembled frame assembly and cooling fluid distribution assembly from the first location to a data center. Block 616 may include, for example, loading the assembled frame assembly and cooling fluid distribution assembly into a shipping container and/or onto a truck for transport and transporting the assembled frame assembly and cooling fluid distribution assembly to the data center for it to be deployed.

The method 600 may further include, at block 618, affixing a plurality of frame assemblies to the data center structure. Block 618 may include, for example, affixing each frame assembly to a ceiling of the data center above locations where associated servers are to be disposed. A frame assembly may be affixed to a ceiling via a plurality of cables and associated fasteners to fasten the cable to the ceiling and to the frame assembly. In some embodiments, the cables may be attached to the data center structure before the frame assemblies are introduced, and block 618 may include simply coupling the cables to the frame assembly. Block 618 may include coupling the cables to eye bolts, loops, or similar structures of the frame assembly.

The method 600 may further include, at block 620, fluidly coupling adjacent fluid distribution assemblies to each other in the data center. For example, inflow pipes of each fluid distribution assembly may be fluidly coupled to the inflow pipes of one or two adjacent fluid distribution assemblies (e.g., one assembly upstream and one assembly downstream). Similarly, outflow pipes of each fluid distribution assembly may be fluidly coupled to the outflow pipes of one or two adjacent distribution assemblies. Adjacent fluid pipes may be coupled together via threaded fittings, crimp fittings, and/or another fluid coupling approach.

The method 600 may further include, at block 622, fluidly coupling the fluid distribution assemblies to one or more server cooling apparatus (e.g., via the taps) and/or fluidly coupling the fluid distribution assemblies to one or more fluid sources (e.g., pumps).

In a first aspect of the present disclosure, a method for assembling a server cooling assembly is provided. The method includes assembling, offsite from a data center, a plurality of frame assemblies, each frame assembly including a plurality of frames affixed to one another with a plurality of longitudinal struts, coupling a respective fluid distribution assembly to each of the frame assemblies, offsite from the data center, transporting the plurality of frame assemblies, with coupled fluid distribution assemblies, to the data center, affixing the frame assemblies to a structure of the data center, and fluidly coupling the plurality of fluid distribution assemblies to one another within the data center.

In an embodiment of the first aspect, assembling the plurality of frame assemblies includes welding a plurality of struts together. In a further embodiment of the first aspect, the frame assemblies and fluid distribution assemblies do not require welding at the data center.

In an embodiment of the first aspect, the method further includes fluidly coupling the plurality of fluid distribution assemblies to a cooling fluid source within the data center.

In an embodiment of the first aspect, the method further includes placing a water-resistant sheath about each fluid distribution assembly, the sheath configured to contain and direct the flow of leaks from the fluid distribution assembly. In a further embodiment of the first aspect, the method further includes coupling a respective moisture sensor assembly to each of the fluid distribution assemblies, wherein each moisture sensor assembly comprises a moisture sensor configured to detect moisture within the sheath and an output device.

In an embodiment of the first aspect, affixing the frame assemblies to a structure of the data center includes suspending each frame assembly from the data center ceiling with one or more cables.

In an embodiment of the first aspect, each frame includes an upper strut, lower strut, left strut, and right strut forming a generally rectangular body that defines a central gap, and at least one additional horizontal strut or at least one additional vertical strut disposed within the gap, wherein the respective fluid distribution assembly is affixed to the at least one additional horizontal strut or at least one additional vertical strut.

In a second aspect of the present disclosure, a cooling system for a set of servers is provided. The system includes a plurality of identical frame assemblies, each frame assembly including a plurality of frames affixed to one another with a plurality of longitudinal struts, assembled off-site from a data center containing the set of servers, a plurality of identical fluid distribution assemblies, with each respective fluid distribution assembly affixed to a respective one of the frame assemblies, wherein the frame assemblies are configured to be independently affixed to a data center structure proximate a set of servers, and wherein the plurality of fluid distribution assemblies are configured to be fluidly coupled to one another on-site at the data center.

In an embodiment of the second aspect, each of the plurality of frame assemblies includes a plurality of welded struts. In a further embodiment of the second aspect, the frame assemblies and fluid distribution assemblies do not require welding at the data center.

In an embodiment of the second aspect, the plurality of fluid distribution assemblies are fluidly coupled to a cooling fluid source within the data center.

In an embodiment of the second aspect, the cooling system further includes a water-resistant sheath disposed about each fluid distribution assembly, the sheath configured to contain and direct the flow of leaks from the fluid distribution assembly. In a further embodiment of the second aspect, the cooling system further includes a respective moisture sensor assembly coupled to each of the fluid distribution assemblies, wherein each moisture sensor assembly comprises a moisture sensor configured to detect moisture within the sheath and an output device.

In an embodiment of the second aspect, the frame assemblies are suspended from the data center ceiling with one or more cables.

The cooling system of claim 9, wherein each frame comprises an upper strut, lower strut, left strut, and right strut forming a generally rectangular body that defines a central gap, and at least one additional horizontal strut or at least one additional vertical strut disposed within the gap, wherein the respective fluid distribution assembly is affixed to the at least one additional horizontal strut or at least one additional vertical strut.

In a third aspect of the present disclosure, a modular structure for cooling a set of servers is provided. The modular structure includes a plurality of modular frame assemblies, each frame assembly comprising a plurality of frames affixed to one another with a plurality of longitudinal struts, assembled off-site from a data center containing the set of servers, wherein each frame assembly is independently affixed to a data center structure proximate the set of servers, and a plurality of modular fluid distribution assemblies, with each respective fluid distribution assembly affixed to a respective one of the frame assemblies, and with adjacent ones of the modular fluid distribution assemblies fluidly coupled to one another, wherein the fluid distribution assemblies are fluidly coupled with a cooling fluid source in the data center.

In an embodiment of the third aspect, each modular frame assembly is 40 feet in length or less, 8 feet in width or less, and 9.5 feet in height or less.

In an embodiment of the third aspect, the modular structure further includes a water-resistant sheath disposed about each fluid distribution assembly, the sheath configured to contain and direct the flow of leaks from the fluid distribution assembly, wherein sheath portions disposed on adjacent fluid distribution assemblies are sealed together.

In an embodiment of the third aspect, the modular structure further includes a respective moisture sensor assembly coupled to each of the fluid distribution assemblies, wherein each moisture sensor assembly comprises a moisture sensor configured to detect moisture within the sheath and an output device.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A method for assembling a server cooling assembly, the method comprising:
assembling, offsite from a data center, a plurality of frame assemblies, each frame assembly comprising:
a plurality of frames affixed to one another with a plurality of longitudinal struts;
coupling a respective fluid distribution assembly to each of the frame assemblies, offsite from the data center;
transporting the plurality of frame assemblies, with coupled fluid distribution assemblies, to the data center;
affixing the frame assemblies to a structure of the data center; and
fluidly coupling the plurality of fluid distribution assemblies to one another within the data center.

2. The method of claim 1, wherein assembling the plurality of frame assemblies comprises welding a plurality of struts together.

3. The method of claim 2, wherein the frame assemblies and fluid distribution assemblies do not require welding at the data center.

4. The method of claim 1, further comprising:
fluidly coupling the plurality of fluid distribution assemblies to a cooling fluid source within the data center.

5. The method of claim 1, further comprising placing a water-resistant sheath about each fluid distribution assembly, the sheath configured to contain and direct the flow of leaks from the fluid distribution assembly.

6. The method of claim 5, further comprising:
coupling a respective moisture sensor assembly to each of the fluid distribution assemblies, wherein each moisture sensor assembly comprises a moisture sensor configured to detect moisture within the sheath and an output device.

7. The method of claim 1, wherein affixing the frame assemblies to a structure of the data center comprises suspending each frame assembly from the data center ceiling with one or more cables.

8. The method of claim 1, wherein each frame comprises an upper strut, lower strut, left strut, and right strut forming a generally rectangular body that defines a central gap, and at least one additional horizontal strut or at least one additional vertical strut disposed within the gap, wherein the respective fluid distribution assembly is affixed to the at least one additional horizontal strut or at least one additional vertical strut.

9. A cooling system for a set of servers, the system comprising:
a plurality of identical frame assemblies, each frame assembly comprising a plurality of frames affixed to one another with a plurality of longitudinal struts, assembled off-site from a data center containing the set of servers;
a plurality of identical fluid distribution assemblies, with each respective fluid distribution assembly affixed to a respective one of the frame assemblies;
wherein the frame assemblies are configured to be independently affixed to a data center structure proximate a set of servers; and
wherein the plurality of fluid distribution assemblies are configured to be fluidly coupled to one another on-site at the data center.

10. The cooling system of claim 9, wherein each of the plurality of frame assemblies comprises a plurality of welded struts.

11. The cooling system of claim 10, wherein the frame assemblies and fluid distribution assemblies do not require welding at the data center.

12. The cooling system of claim 9, wherein the plurality of fluid distribution assemblies are fluidly coupled to a cooling fluid source within the data center.

13. The cooling system of claim 9, further comprising a water-resistant sheath disposed about each fluid distribution assembly, the sheath configured to contain and direct the flow of leaks from the fluid distribution assembly.

14. The cooling system of claim 13, further comprising a respective moisture sensor assembly coupled to each of the fluid distribution assemblies, wherein each moisture sensor assembly comprises a moisture sensor configured to detect moisture within the sheath and an output device.

15. The cooling system of claim 9, wherein the frame assemblies are suspended from the data center ceiling with one or more cables.

16. The cooling system of claim 9, wherein each frame comprises an upper strut, lower strut, left strut, and right strut forming a generally rectangular body that defines a central gap, and at least one additional horizontal strut or at least one additional vertical strut disposed within the gap, wherein the respective fluid distribution assembly is affixed to the at least one additional horizontal strut or at least one additional vertical strut.

17. A modular structure for cooling a set of servers, the modular structure comprising:
a plurality of modular frame assemblies, each frame assembly comprising a plurality of frames affixed to one another with a plurality of longitudinal struts, assembled off-site from a data center containing the set of servers, wherein each frame assembly is independently affixed to a data center structure proximate the set of servers; and
a plurality of modular fluid distribution assemblies, with each respective fluid distribution assembly affixed to a respective one of the frame assemblies, and with adjacent ones of the modular fluid distribution assemblies fluidly coupled to one another;
wherein the fluid distribution assemblies are fluidly coupled with a cooling fluid source in the data center.

18. The modular structure of claim 17, wherein each modular frame assembly is 40 feet in length or less, 8 feet in width or less, and 9.5 feet in height or less.

19. The modular structure of claim 17, further comprising a water-resistant sheath disposed about each fluid distribution assembly, the sheath configured to contain and direct the flow of leaks from the fluid distribution assembly, wherein sheath portions disposed on adjacent fluid distribution assemblies are sealed together.

20. The modular structure of claim 19, further comprising a respective moisture sensor assembly coupled to each of the fluid distribution assemblies, wherein each moisture sensor assembly comprises a moisture sensor configured to detect moisture within the sheath and an output device.
